(19) United States
(12) Patent Application Publication
(10) Pub. No.: US 2024/0133031 A1
(43) Pub. Date: Apr. 25, 2024

(54) FILM FORMING DEVICE AND FILM FORMING METHOD

(71) Applicant: TOKYO ELECTRON LIMITED, Tokyo (JP)

(72) Inventor: Jun YAMAWAKU, Nirasaki City, Yamanashi (JP)

(21) Appl. No.: 18/275,359

(22) PCT Filed: Jan. 26, 2022
(86) PCT No.: PCT/JP2022/002936

§ 371 Date: Jul. 31, 2023

(30) Foreign Application Priority Data
Feb. 9, 2021 (JP) 2021-019330

(51) Int. Cl. C23C 16/455; C23C 16/505; C23C 16/52; H01J 37/32

(52) U.S. Cl. CPC C23C 16/45536; C23C 16/45544; C23C 16/45565; C23C 16/505; C23C 16/52; H01J 37/32449; H01J 2237/3321

(57) ABSTRACT

[Solution] A device according to the present disclosure comprises: a plasma generation chamber that is provided with a plasma generation mechanism for activating a second processing gas, when forming a film on a substrate by supplying each of a first processing gas, a substitution gas, the plasma-activated second processing gas, and the substitution gas, in order and by turns, to a processing vessel in which an interior processing space is evacuated so as to become a vacuum atmosphere; an evacuation mechanism that evacuates the plasma generation chamber; and a supply destination changing valve that is provided on an evacuation path connecting the plasma generation chamber and the evacuation mechanism, and opens and closes such that the supply destination of the plasma-activated second processing gas switches between a downstream side of the evacuation path, and the processing space.

### TECHNICAL FIELD

The present disclosure relates to a film forming apparatus and a film forming method.

### BACKGROUND

In a semiconductor manufacturing process, when a film is formed on a substrate by atomic layer deposition (ALD), for example, plasma enhanced-ALD (PEALD) using gas-excited plasma may be performed. Patent Document 1 discloses a technique for forming a film by activating a carrier gas of a film forming material or a reducing gas using plasma by supplying a high frequency power to a gap between a gas shower head and a lower electrode.

### PRIOR ART DOCUMENTS

### Patent Documents

Patent Document 1: Japanese Laid-open Patent Publication No. 2005-248231

### SUMMARY

### Problems to Be Resolved by the Invention

The present disclosure provides a technique for improving throughput in forming a film on a substrate by alternately supplying a first processing gas and a second processing gas activated by plasma to the substrate.

### Means for Solving the Problems

The film forming apparatus of the present disclosure includes a processing vessel accommodating a substrate and having therein a processing space evacuated to a vacuum atmosphere, and forms a film on a substrate by performing multiple times a cycle of supplying to the processing space a first processing gas, a substitution gas for replacing an atmosphere of the processing space, and a plasma-activated second processing gas, and the substitution gas in that order, the film forming apparatus comprising: a plasma generation chamber provided with a plasma generation mechanism configured to activate the second processing gas; an evacuation mechanism configured to evacuate the plasma generation chamber; a first flow path disposed in the processing vessel to supply the first processing gas to the processing space; a second flow path that is partitioned from the first flow path such that a downstream end is opened to the processing space and an upstream end is connected to the plasma generation chamber, and is not opened or closed by a valve; a gas supply mechanism configured to supply the first processing gas, the second processing gas, and the substitution gas to the first flow path, the plasma generation chamber, and a substitution gas flow path configured to supply the substitution gas to the processing space, respectively; and a supply destination changing valve that is disposed at any position on an evacuation path that connects the plasma generation chamber and the evacuation mechanism, and configured to be opened and closed during repetitive execution of the cycle so that a supply destination of the plasma-excited second processing gas switches between a downstream side of the position on the evacuation path and the processing space.

### Effect of the Invention

In accordance with the present disclosure, it is possible to improve the throughput in forming a film on a substrate by alternately supplying a first processing gas and a second processing gas activated by plasma to the substrate.

### BRIEF DESCRIPTION OF THE DRAWINGS

FIG. 1 is a longitudinal side view showing a film forming apparatus according to one embodiment.

FIG. 2 is an explanatory diagram of a plasma generation chamber constituting a plasma generation part of a first example.

FIG. 3 is a timing chart showing gas supply timing or the like in an example of film formation performed by a film forming apparatus.

FIG. 4 is a longitudinal side view for explaining an operation of the film forming apparatus.

FIG. 5 is a longitudinal side view for explaining the operation of the film forming apparatus.

FIG. 6 is a longitudinal side view for explaining the operation of the film forming apparatus.

FIG. 7 is a longitudinal side view showing a second example of the plasma generation part.

FIG. 8 is a longitudinal side view showing a first example of a gas shower head.

FIG. 9 is a longitudinal side view showing a second example of the gas shower head.

FIG. 10 is a longitudinal side view showing a third example of the gas shower head.

FIG. 11 is a longitudinal side view showing a fourth example of the gas shower head.

FIG. 12 is a longitudinal side view showing a fifth example of the gas shower head.

FIG. 13 is a longitudinal side view showing a third example of the plasma generation part.

### DETAILED DESCRIPTION

### First Embodiment of Film Forming Apparatus

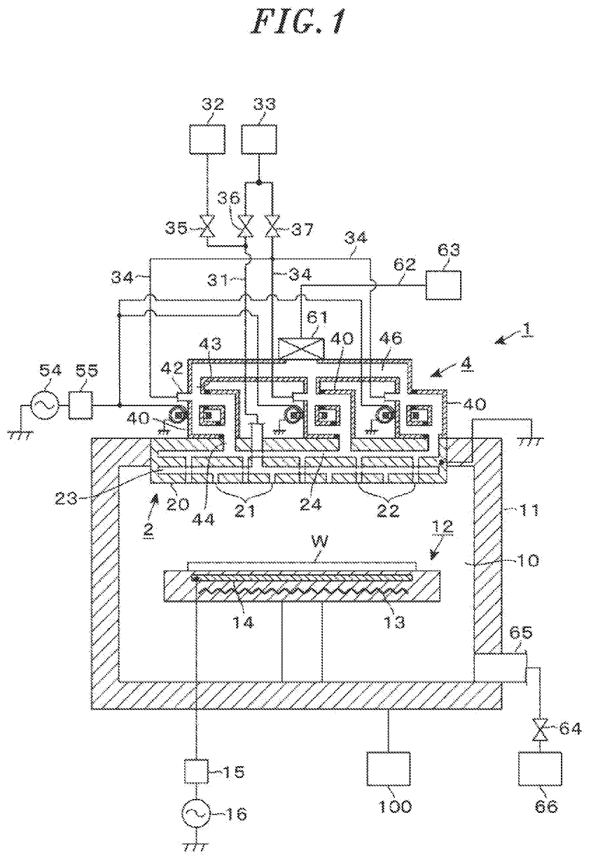

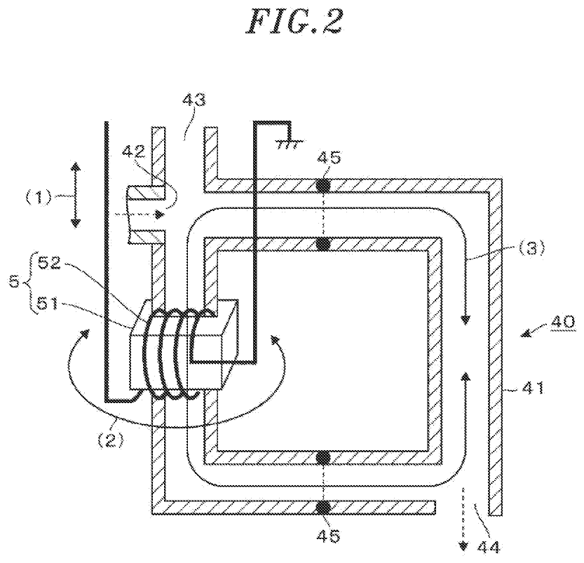

A film forming apparatus according to an embodiment of the present disclosure will be described with reference to FIGS. 1 and 2. A film forming apparatus 1 of the present disclosure forms, for example, a Ti (titanium) film on a wafer W that is a substrate by plasma enhanced atomic layer deposition (PEALD). The film forming apparatus 1 includes, for example, a circular processing vessel 11 accommodating the wafer W and defining a processing space 10. A placing table 12 on which the wafer W is placed is disposed in the processing vessel 11, and a heater 13 for heating the wafer W to a processing temperature is embedded in the placing table 12. Further, an electrode 14 is embedded in the placing table 12 of this example, and a radio frequency (RF) power supply 16 is connected to the electrode 14 through a matching device 15. The RF power supply 16 applies an RF power (RF bias) for attracting ions to the wafer W to the placing table 12. Further, the placing table 12 is provided with a lifting mechanism (not shown) for the wafer W.

The ceiling portion of the processing vessel 11 is configured as a gas shower head 2 having a circular shape in plan view and configured to supply a gas to the wafer W in a shower pattern. The gas shower head 2 is made of a conductive material, and is grounded. A bottom surface 20 of the gas shower head 2 is greater than, for example, the wafer W placed on the placing table 12 in plan view, and has a plurality of first injection holes 21 and a plurality of second injection holes 22 formed vertically to be opened to the processing space 10.

The first injection holes 21 are distributed on the entire bottom surface 20 of the gas shower head 2. Further, in the gas shower head 2, a first gas diffusion space 23 commonly used for the first injection holes 21 is formed at the upstream side of the first injection holes 21. Therefore, all the first injection holes 21 are connected to the first gas diffusion space 23. In this example, a first channel formed in the processing vessel 11 includes the first injection holes 21 and the first gas diffusion space 23, and also serves as a channel for a first processing gas and a channel for a substitution gas, to be described later.

The second injection holes 22 are distributed on the entire bottom surface 20 of the gas shower head 2. Further, in the gas shower head 2, a second gas diffusion space 24 commonly used for the second injection holes 22 is formed at the upstream side of the second injection holes 22. Therefore, all the second injection holes 22 are connected to the second gas diffusion space 24. In this example, the second channel includes the second injection holes 22 and the second gas diffusion space 24, and is partitioned from the first channel. Further, in this example, the second gas diffusion space 24 is disposed above the first gas diffusion space 23.

The first gas diffusion space 23 is connected to each of a first processing gas supply source 32 and a second processing gas supply source 33 through a first gas supply line 31. The second gas diffusion space 24 is connected to the second processing gas supply source 33 via plasma generation chambers 40 to be described later by a second gas supply line 34. In the drawing, reference numerals 35, 36 and 37 indicate flow rate control valves. A gas supply mechanism of the present disclosure includes the first process gas supply source 32, the second process gas supply source 33, the first gas supply line 31, and the second gas supply line 34.

For example, titanium tetrachloride (TiCl₄) that is a material gas can be used as the first processing gas, and argon (Ar) gas that is a reaction gas can be used as the second processing gas. In this example, the same type of gas is used as the second processing gas (reaction gas) and the substitution gas (purge gas). Therefore, Ar gas is used as the substitution gas, and the second processing gas and the substitution gas are supplied from the second processing gas supply source 33. In this manner, the first processing gas and the substitution gas are injected from the first injection holes 21 into the processing space 10 through the first gas supply line 31 and the first gas diffusion space 23. Further, the plasma-activated reaction gas is injected from the second injection holes 22 into the processing space 10 through the second gas diffusion space 24. Hereinafter, the material gas will be described as the first processing gas, and the reaction gas will be described as the second processing gas.

The plasma generation chambers 40 are stacked on the upper surface of the gas shower head 2. In this example, the plurality of plasma generation chambers 40 are combined to form a plasma generation part 4. This plasma generation part 4 is described as a first example of the plasma generation part.

Next, the plasma generation chamber 40 will be described with reference to FIG. 2. The plasma generation chamber 40 includes, for example, a pipe body 41 forming an annular space for generating plasma, and a plasma generation mechanism 5 for generating a plasma current that flows when plasma is produced from a gas and circulating the plasma current in the pipe body 41.

The pipe body 41 has a metal wall. The pipe body 41 has an annular shape that stands upright in a rectangular shape, so that the above-described annular space is formed in the pipe body 41. The pipe body 41 is installed such that the surface including the annular space becomes perpendicular to a horizontal direction. More specifically, the pipe body 41 has two portions (referred to as “horizontal portions”) extending horizontally along the upper surface of the gas shower head 2. These horizontal portions are separated from each other in a lateral direction. The pipe body 41 has two portions (referred to as “vertical portions”) extending vertically to connect both ends of the horizontal portions. These vertical portions are separated from each other in a horizontal direction. The pipe body 41 has an inlet 42 for supplying a reaction gas thereinto, and a first outlet 43 and a second outlet 44 for discharging a plasma-activated reaction gas. The first outlet 43 opens upward at one of the two vertical portions. The second outlet 44 opens downward at the other vertical portion. The inlet 42 opens sideward at the one vertical portion, for example. Further, the pipe body 41 has dielectrics 45 to prevent a plasma current generated in the annular space from dissipating along the wall. Specifically, each of the horizontal portions is formed by connecting pipes via the dielectrics 45.

The plasma generation mechanism 5 includes an annular magnetic core (yoke) 51 surrounding a part of the wall of the pipe body 41, a coil 52 formed by winding a copper wire around a part of the yoke 51 in a spiral shape, and an RF power supply 54 (see FIG. 1) for supplying a power to the coil 52. When the power is supplied from the RF power supply 54 to the coil 52, an annular yoke magnetic field 2 is generated by a current 1 flowing through the coil 52 to surround the inside of the yoke 51, that is, the circumference of the pipe body 41.

Further, when the reaction gas is supplied from the inlet 42 into the pipe body 41, the reaction gas is turned into plasma by the yoke magnetic field 2, and a toroidal plasma current 3 circulating in the annular space in the pipe body 41 is generated. The plasma-activated gas contains radicals and ions. The activated reaction gas is discharged from the first outlet 43 or the second outlet 44 as will be described later.

The plasma generation part 4 has a structure in which multiple plasma generation chambers 40 are installed as shown in FIG. 1, and the plasma generation chambers 40 are arranged in the lateral direction, e.g., in the horizontal direction, on the upper surface of the gas shower head 2.

An RF power of, for example, 400 kHz, is supplied from the common RF power supply 54 to the coil 52 of each plasma generation mechanism 5. Reference numeral 55 in FIG. 1 denotes a matching device, and the RF power with the same phase is supplied from the common RF power supply 54 to each coil 52. Hereinafter, in this example, the RF power supply 54 for plasma generation will be described as a first RF power supply, and the RF power supply 16 for bias power application will be described as a second RF power supply.

The reaction gas inlet 42 of each plasma generation chamber 40 is connected to the second processing gas supply source 33 through the second gas supply line 34 as described above. Further, each plasma generation chamber 40 is installed such that each second outlet 44 is connected to the second gas diffusion space 24 formed in the gas shower head 2. In this manner, the second channel, having a downstream end that opens to the processing space 10 and an upstream end side connected to each plasma generation chamber 40, is not opened and closed by a valve.

In addition, an evacuation space (common evacuation space) 46 commonly used for the plasma generation chambers 40 is formed above the plasma generation chambers 40, and the plasma generation chambers 40 are connected to the common evacuation space 46 through the respective first outlets 43. The common evacuation space 46 is connected to a first evacuation mechanism 63 through a first evacuation path 62 having a supply destination changing valve 61. In this example, the supply destination changing valve 61 is installed to be close to the common evacuation space 46. More specifically, the supply destination changing valve 61 is stacked on a member forming the common evacuation space 46, for example. On the other hand, the bottom portion of the processing vessel 11 is connected to a second evacuation mechanism 66 through a second evacuation path 65 having a valve 64. The first evacuation mechanism 63 and the second evacuation mechanism 66 include vacuum pumps, for example.

The supply destination changing valve 61 is opened and closed such that the supply destination of the plasma-activated reaction gas is switched between the processing space 10 and the downstream side of the position where the supply destination changing valve 61 is installed in the first evacuation path 62. More specifically, the reaction gas is switched between the state in which it is evacuated by the first evacuation mechanism 63 and the state in which it is evacuated by the second evacuation mechanism 66. As will be described later, the processing vessel 11 is evacuated by the second evacuation mechanism 66 so that the processing space 10 is maintained at a vacuum atmosphere during film formation. When the supply destination changing valve 61 is opened in this state, the plasma generation chambers 40 are evacuated by the first evacuation mechanism 63, and the plasma-activated reaction gas is supplied to the downstream side of the first evacuation path 62. The balance of the evacuation amounts by the first evacuation mechanism 63 and the second evacuation mechanism 66 and the conductance of the flow path are set to form the above-described flow of the reaction gas. When the supply destination changing valve 61 is opened, the reaction gas is evacuated from the first evacuation mechanism 63 without leaking through the second injection holes 22 in order to prevent unnecessary reaction with the material gas.

On the other hand, when the supply destination changing valve 61 is closed, the plasma generation chambers 40 are evacuated by the second evacuation mechanism 66 disposed at the bottom portion of the processing vessel 11, so the plasma-activated reaction gas is supplied to the processing space 10. As described above, when it is not necessary to supply the plasma-activated reaction gas to the processing space 10, the plasma-activated reaction gas is evacuated by the first evacuation mechanism 63 without passing through the processing space 10. Therefore, no valve is disposed in the flow path that connects the plasma generation chambers 40 and the processing space 10.

The first evacuation mechanism 63 evacuates a gas from the upper portions of the plasma generation chambers 40, and the second evacuation mechanism 66 evacuates a gas from the bottom portion of the processing vessel 11. Therefore, the evacuation by the first evacuation mechanism 63 may be referred to as “upward evacuation” and the evacuation by the second evacuation mechanism 66 may be referred to as “downward evacuation.” A loading/unloading port (not shown) for loading/unloading the wafer W is formed in the sidewall of the processing vessel 11 to be opened and closed by a gate valve.

As shown in FIG. 1, the film forming apparatus 1 includes a controller 100 including a computer, and the controller 100 has a program. This program incorporates instructions for transmitting control signals from the controller 100 to individual components of the film forming apparatus 1 and performing processing to be described later. Specifically, the operations of the valves such as the supply destination changing valve 61 and the like, the heater 13 in the placing table 12, the RF power supplies 16 and 54, the first and second evacuation mechanisms 63 and 66, and the like are controlled by the program. This program is stored in a storage medium such as a compact disc, a hard disk, a memory card, a DVD, or the like, and is installed in the controller 100.

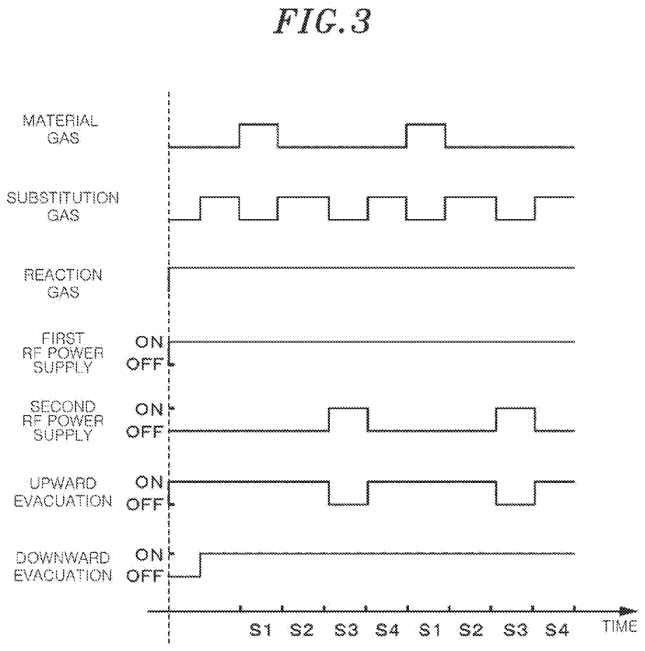

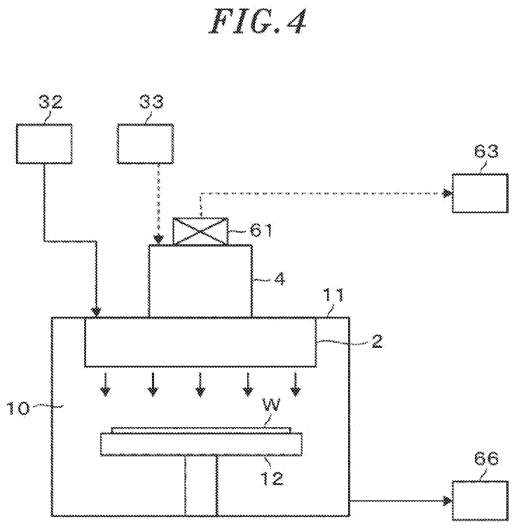

Next, a film forming method using the film forming apparatus 1 according to the present disclosure will be described with reference to FIGS. 3 to 6. In FIGS. 4 to 6, solid lines indicate the flow of the material gas, dashed lines indicate the flow of the reaction gas, and dashed-dotted lines indicate the flow of the substitution gas.

First, a gate valve (not shown) is opened, and the wafer W is loaded into the processing vessel 11 and placed on the placing table 12. The placing table 12 is heated by the heater 13 to a preset temperature. Then, the valve 37 is opened to supply the reaction gas (second processing gas) from the inlet 42 of each plasma generation chamber 40, and the RF power is applied from the first RF power supply 54 to the coil 52 of each plasma generation mechanism 5. Further, the supply destination changing valve 61 is opened, and the first evacuation mechanism 63 performs the upward evacuation.

When the RF power is supplied from the first RF power supply 54 to each plasma generating mechanism 5, the reaction gas is activated by plasma in the pipe body 41 as described above. Then, since the supply destination changing valve 61 is opened, the activated reaction gas is evacuated from the first evacuation path 62 to the first evacuation mechanism 63 through the first outlet 43. As shown in FIG. 3, the supply of the reaction gas to the plasma generation part 4 and the application of the RF power from the first RF power supply 54 to the plasma generation part 4 are continuously performed during the film formation.

Next, the valve 36 is opened to start the supply of the substitution gas, and the valve 64 is opened to start the downward evacuation by the second evacuation mechanism 66, thereby evacuating the processing space 10 to a vacuum atmosphere. Thereafter, the downward evacuation is continuously performed by the second evacuation mechanism 66. The substitution gas is supplied to the first gas diffusion space 23 of the gas shower head 2, and is discharged from the first injection holes 21 into the processing space 10.

Then, the valve 36 is closed to stop the supply of the substitution gas, and the valve 35 is opened to start the supply of the material gas (first processing gas). As shown in FIG. 4, the material gas is discharged into the processing space 10 from the first injection holes 21 through the first gas diffusion space 23 of the gas shower head 2. Even during the supply of the material gas, as described above, the supply of the reaction gas and the application of the RF power from the first RF power supply 54 are continued, but the plasma-activated reaction gas is discharged from the first evacuation mechanism 63 through the first evacuation path 62, as described above.

As described above, when the material gas is supplied, the evacuation is also performed by the first evacuation mechanism 63 as well as the second evacuation mechanism 66. The pressure loss in the gas shower head 2 or the balance of the evacuation amounts of the upward evacuation and the downward evacuation is controlled to suppress the flow of the material gas discharged to the processing space 10 into the plasma generation chambers 40 through the second injection holes 22. Accordingly, the material gas and the reaction gas are prevented from reacting in the flow paths in the gas shower head 2 or the plasma generation chambers 40 to form a film on the walls of the flow paths or the plasma generation chambers 40.

In this manner, TiCl₄ as a film forming material is supplied into the processing space 10 and adsorbed on the entire surface of the wafer W (step S1). Next, the valve 35 is closed to stop the supply of the material gas, and the valve 36 is opened to start the supply of the substitution gas.

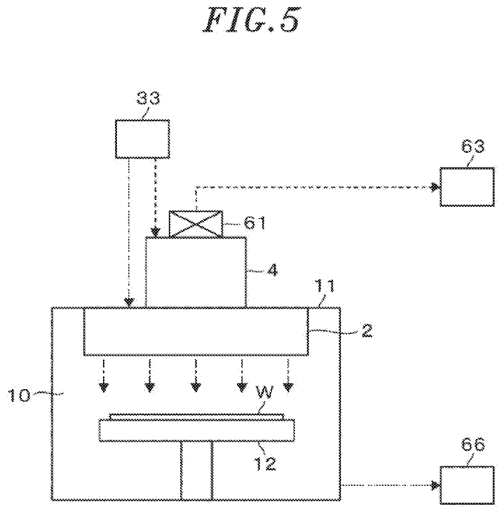

As shown in FIG. 5, the substitution gas is supplied to the processing space 10 through the first injection holes 21 of the gas shower head 2, thereby purging the inside of the processing vessel 11 and eliminating the material gas remaining in the processing vessel 11 (step S2). Even when the substitution gas is supplied, the balance between the supply flow rate of the substitution gas and the evacuation is controlled to suppress the inflow of the substitution gas into the plasma generation chambers 40.

Next, the valve 36 is closed to stop the supply of the substitution gas, and the supply destination changing valve 61 is closed to stop the upward evacuation by the first evacuation mechanism 63 and to start the supply of the reaction gas (the second processing gas) to the processing space 10.

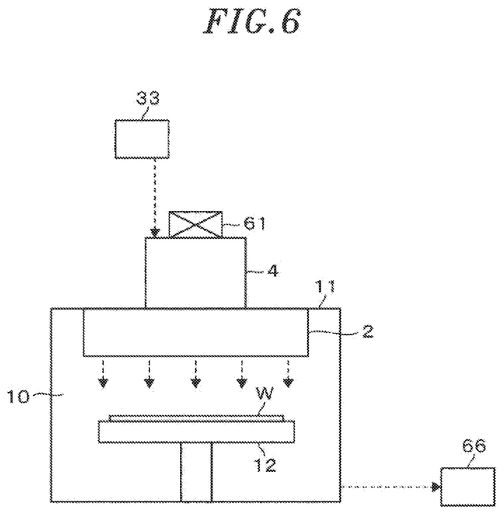

When the supply destination changing valve 61 is closed, the supply destination of the reaction gas is switched to the processing space 10 side as described above. In other words, as shown in FIG. 6, the reaction gas is discharged into the processing space 10 through the second injection holes 22.

In this example, when the reaction gas is supplied to the processing vessel 11, the RF power for RF bias is applied by the second RF power supply 16, and an electric field is generated between the placing table 12 and the bottom surface 20 of the gas shower head 2. Due to the generation of the electric field, ions contained in the plasma-excited reaction gas are attracted to the wafer W. Therefore, the plasma-excited reaction gas containing a relatively large amount of ions reacts with the TiCl₄ gas adsorbed on the wafer W react, thereby reducing TiCl₄ and forming a Ti film on the wafer W (step S3). The application of the RF bias to the placing table 12 is used for controlling the amount of ions attracted to the wafer W depending on types of film formation. The application of the RF bias to the placing table 12 is not necessarily performed, and may be performed if required. Further, the remaining amount of the reaction gas supplied to the processing space 10 is evacuated from the processing space 10 by the second evacuation mechanism 66.

Next, the supply destination changing valve 61 is opened to start the upward evacuation by the first evacuation mechanism 63, and the valve 36 is opened to start the supply of the substitution gas. Accordingly, the plasma-excited reaction gas in the plasma generation chambers 40 is evacuated again by the first evacuation mechanism 63 through the first evacuation path 62, and only the substitution gas is supplied into the processing space 10 through the first injection holes 21. The substitution gas supplied into the processing space 10 is evacuated by the second evacuation mechanism 66. Accordingly, the inside of the processing vessel 11 is purged, and the activated reaction gas remaining in the processing vessel 11 is eliminated (step S4).

In this manner, the cycle of steps S1 to S4 in which the material gas, the substitution gas, the plasma-activated reaction gas, and the substitution gas are supplied in that order to the processing space 10 is repeated, thereby forming a Ti film of a desired film thickness on the wafer W by ALD.

In accordance with the present embodiment, the reaction gas is always activated by the plasma in the plasma generation chambers 40 during the film formation, and the supply destination of the activated reaction gas is switched between the downstream side of the supply destination changing valve 61 and the processing space 10 by the supply destination changing valve 61. Therefore, start and stop of supply of the reaction gas to the processing space 10 can be controlled only by opening and closing the supply destination changing valve 61 during the repeated cycle of ALD. Hence, compared to the case of activating the reaction gas with plasma whenever the reaction gas is supplied, the time required for plasma ignition becomes unnecessary, which makes it possible to improve the throughput.

More specifically, in order to decrease the throughput of PEALD, it is considered to shorten the supply time of the plasma-activated reaction gas and, thus, it is effective to increase reactivity by producing plasma of a reaction gas having a relatively high density (relatively high activity). In the case of producing high-density plasma, there is a tendency in which a certain amount of time is required until the plasma is ignited and stabilized. In the process of repetitively supplying the plasma-excited reaction gas, such as ALD, the accumulation of time required for the ignition may affect the throughput. Therefore, as in this example, in the configuration in which plasma is always/constantly produced during the film formation and the reaction gas is supplied at desired timing by opening and closing the valve, the influence of the time required for the ignition on the throughout is eliminated, so that the throughput can be improved.

Even if plasma having a relatively high density is produced, when the plasma acts unevenly on the wafer W, the processing on the surface of the wafer W becomes non-uniform. However, in this example, the plasma-excited reaction gas in the plasma generation chambers 40 is supplied through the second injection holes 22 of the gas shower head 2. Since the reaction gas passes through the gas shower head 2, the reaction gas is uniformly distributed and supplied to the surface of the wafer W. Therefore, in accordance with the present embodiment, the film formation can be performed while ensuring in-plane uniformity of the wafer W. Since the material gas is also supplied to the wafer W through the gas shower head 2, the film formation can be performed while more reliably ensuring the in-plane uniformity of the wafer W.

The plasma generation chambers 40 are stacked on the gas shower head 2, and the second outlet 44 is connected to the gas shower head 2. Thus, plasma is generated near the wafer W in the processing vessel 11, and is quickly supplied to the processing space 10. Accordingly, even if the flow path of the gas shower head 2 is interposed between the plasma generation chambers 40 and the processing space 10, it is possible to suppress deactivation of the plasma, and also possible to perform film formation on the wafer W using the high-density plasma.

Further, since the plasma generation part 4 is formed by arranging multiple plasma generation chambers 40 in the lateral direction, the uniformity of the density of the plasma supplied to each part of the second gas diffusion space 24 in the gas shower head 2 can be improved. Due to such arrangement of the plasma generation chambers 40, the uniformity of the plasma processing on each part of the wafer W can be further improved.

In the above embodiment, the common evacuation space 46 is provided for the plasma generation chambers 40, and the common supply destination changing valve 61 is used to switch the supply destination of the plasma-excited reaction gas. Since one supply destination changing valve 61 is provided, it is possible to facilitate switching control and simplify the configuration even when there are multiple plasma generation chambers 40. Further, in this example, the supply destination changing valve 61 is disposed near the plasma generation chambers 40. Therefore, when the supply destination changing valve 61 is switched from a closed state to an open state, the reaction gas can be quickly discharged from the plasma generation chambers 40 to the first evacuation path 62. In other words, it is possible to quickly change the flow direction of the reaction gas, and also possible to more reliably suppress the inflow of the reaction gas into the processing space 10 when it is not required.

In the above-described embodiment, the RF bias can be applied to the placing table 12, and the gas shower head 2 is grounded. Therefore, the plasma-activated reaction gas can be supplied from the gas shower head 2 to the processing space 10, and ions can be attracted to the wafer W by applying the RF bias to the placing table 12 depending on types of film formation. As will be described later, the film formation is not limited to the above-described Ti film formation. Depending on types of film formation, the quality of the film may be improved by introducing ions. Therefore, the configuration in which the supply of the activated reaction gas and the attraction of ions can be controlled independently is effective. Since the gas shower head 2 facing the entire surface of the wafer W serves as a ground electrode, an electric field is generated on the entire surface of the wafer W when the RF power is supplied to the placing table 12 and, thus, the attraction of ions is performed on the surface of the wafer W while ensuring high uniformity. From the above, the uniformity of processing on the surface of the wafer W is improved.

### Second Example of Plasma Generation Part 4

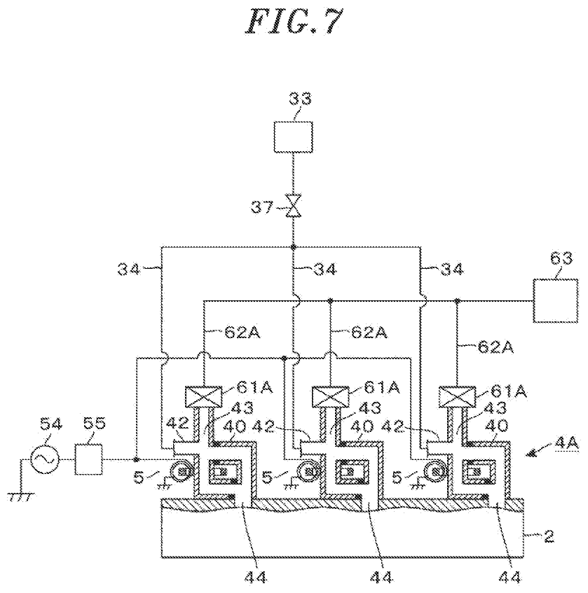

Next, a second example of the plasma generation part will be described with reference to FIG. 7. In a plasma generation part 4A of this example, when a plurality of plasma generation chambers 40 are provided, each plasma generation chamber 40 is provided with a supply destination changing valve 61A. The first outlet 43 of each plasma generation chamber 40 is connected to the common first evacuation mechanism 63 through each evacuation path 62A, and each evacuation path 62A is provided with the supply destination changing valve 61A. Although the other components except the configuration related to the plasma generation part 4A are not illustrated, the other components are the same as those of the first embodiment.

In this configuration, the opening/closing operations of the supply destination changing valves 61A of the plasma generation chambers 40 are performed at the same time, and the controller 100 controls the opening/closing of the supply destination changing valves 61A in the same manner as that in the above-described first embodiment.

It is not necessary that the plasma generation part 4 is formed by arranging the multiple plasma generation chambers 40. For example, one plasma generation chamber 40 shown in FIG. 7 may be used.

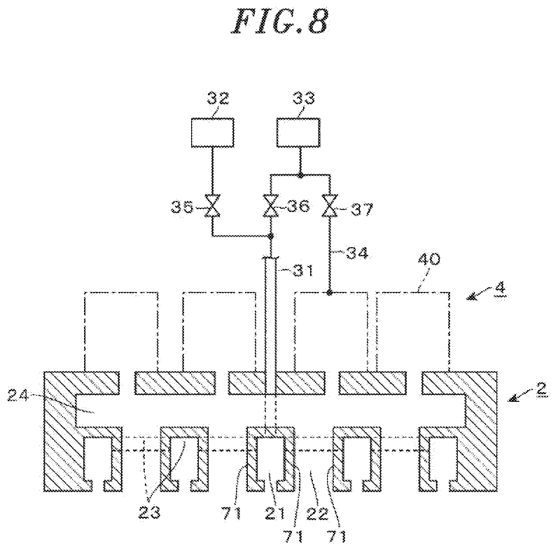

FIG. 8 is a longitudinal side view schematically showing an enlarged view of the above-described gas shower head 2. The second injection holes 22 of the gas shower head 2 will be described further. Sidewalls 71 forming the first injection holes 21 and the second injection holes 22 extend in the vertical direction. In the example shown in FIG. 8, the lower parts of the sidewalls 71 forming the first injection hole 21 protrude toward the center of the hole, thereby forming a narrow portion. However, such a narrow portion may not be formed. In the following description, the gas shower head 2 may be described as a first example of the gas shower head.

### Second Example of Gas Shower Head

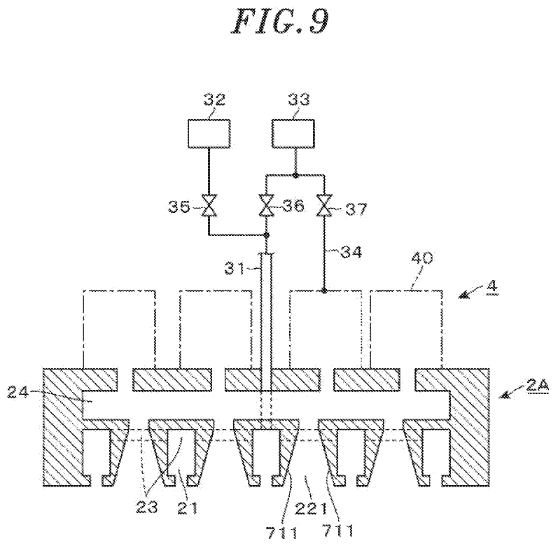

Next, a second example of the gas shower head will be described with reference to FIG. 9. A gas shower head 2A of this example is different from the gas shower head 2 of the first example in that second injection holes 221 (corresponding to the second injection holes 22 of the first example) has a shape that becomes wider downward (i.e., a tapered shape that becomes narrower upward). The other components are the same as those of the gas shower head 2 of the first example.

Radicals forming the plasma are likely to be deactivated by the collision with the walls forming the flow paths. Due to the above-described shape of the second injection holes 221, the radicals that have entered the second injection holes 221 are less likely to collide with sidewalls 711 forming the second injection holes 221 when they are directed toward the processing space 10 disposed thereunder. Hence, the radials are less likely to be deactivated with respect to the second injection holes 221.

The pressure loss of the second injection holes 221 is determined at a portion having a smallest hole diameter. Due to the above-described shape of the second injection holes 221, the upper portion thereof may have a relatively small hole diameter. Therefore, the pressure loss of the gas flowing from the processing space 10 to the second injection holes 221 is relatively large, and the inflow of the gas from the second injection holes 221 into the second gas diffusion space 24 can be more reliably prevented. In other words, in accordance with the gas shower head 2A, the deactivation of radicals can be suppressed to supply relatively high-density plasma to the wafer W, and the material gas in the processing space 10 can be more reliably prevented from being discharged through the second injection holes 221, entering the gas shower head 2A, and reacting with the reaction gas.

### Third Example of Gas Shower Head

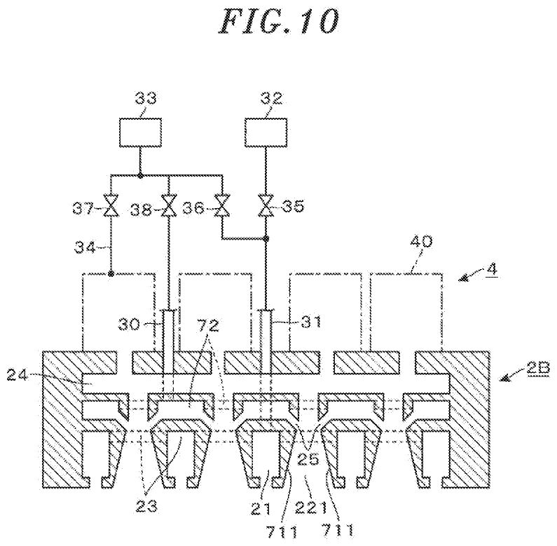

Next, a third example of the gas shower head will be described with reference to FIG. 10. A gas shower head 2B of this example is different from the gas shower head 2A of the second example in that third injection holes 25 for discharging a gas into the second injection holes 221 are formed. The third injection holes 25 open in the sidewalls 711 forming the second injection holes 221.

In the gas shower head 2B, a third gas diffusion space 72 is disposed between the first gas diffusion space 23 and the second gas diffusion space 24, and the third injection holes 25 are connected to the third gas diffusion space 72. The third injection holes 25 are formed to discharge a gas obliquely downward, and the opening direction of the third injection holes 25 is directed toward the sidewalls 711. Therefore, in the sidewalls 711, the third injection holes 25 discharge a gas to a position lower than the opening positions thereof.

The third gas diffusion space 72 is connected to the second processing gas supply source 33 through a third gas supply line 30 having a valve 38. The third gas supply line 30 and the third gas diffusion space 72 form a third flow path partitioned from the first flow path and the second flow path. In other words, the second processing gas supplied from the third gas supply line 30 to the gas shower head 2B is not supplied to the first gas diffusion space 23 and the second gas diffusion space 24, and is supplied to the third gas diffusion space 72, and discharged from the third injection holes 25. In this manner, the gas is supplied from the second processing gas supply source 33 to the third injection holes 25. As will be described later, this gas is used as a substitution gas (purge gas) and as a sealing gas for the injection holes. However, for simplicity of description, it is described as a substitution gas. In the gas shower head 2B, the gas supply line 30, the third gas diffusion space 72, and the third injection holes 25 in addition to the first gas diffusion space 23 and the first injection holes 21 form a substitution gas flow path.

In the gas shower head 2B, the material gas and the substitution gas are discharged from the first injection holes 21 at the same timings as those described in steps S1 to S4, and the plasma-activated reaction gas is discharged from the second injection holes 221. Further, during the period in which the supply destination changing valve 61 is opened and the reaction gas is upwardly evacuated, the substitution gas is discharged from the third injection holes 25 into the second injection holes 221 via the third gas diffusion spaces 72. During the period in which the supply destination changing valve 61 is closed and the reaction gas is supplied to the processing space 10, the discharge of the substitution gas from the third injection holes 25 is stopped.

Accordingly, when the supply destination changing valve 61 is opened and the upward evacuation is performed, the second injection holes 221 are sealed by the substitution gas discharged from the third injection holes 25. Hence, due to the flow of the substitution gas, the plasma-activated reaction gas is prevented from leaking into the processing space 10 and the material gas is prevented from flowing into the plasma generation part 4.

Since the third injection holes 25 are formed to discharge a gas downward, a substitution gas flow is formed from the plasma generation part 4 toward the processing vessel 11. Accordingly, the material gas is pushed toward the processing space 10 by the substitution gas flow, and the flow of the material gas toward the plasma generation part 4 can be further suppressed. The gas discharged from the third injection holes 25 is evacuated through the processing space 10. Therefore, the gas discharged from the third injection holes 25 seals the second injection holes 221 (forms a gas curtain) as described above during the execution of steps S1, S2, and S4. During the execution of steps S2 and S4, it serves as a substitution gas for replacing the atmosphere in the processing vessel 11 together with the substitution gas discharged from the first injection holes 21. It is also possible to perform the discharge of the gas from the third injection holes 25 only during the execution of step S1. In other words, the gas discharged from the third injection holes 25 may be used only for sealing the second injection holes 221, and may not be used as a substitution gas.

### Fourth Example of Gas Shower Head

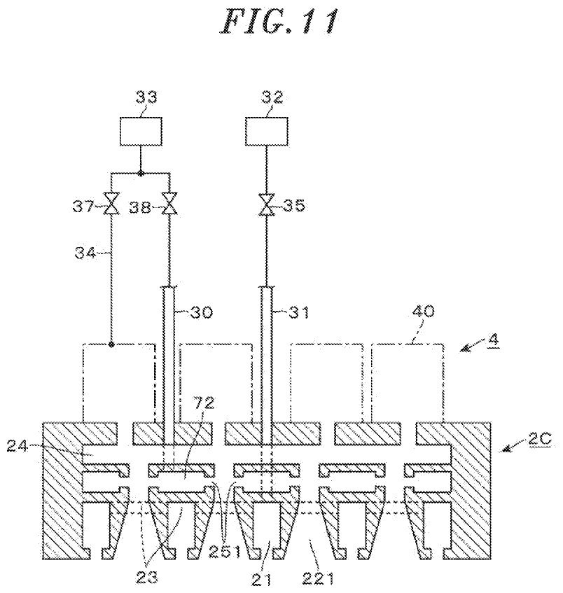

A fourth example of the gas shower head will be described with reference to FIG. 11. A gas shower head 2C of this example is different from the gas shower head 2B of the third example in that the opening direction of third injection holes 251 corresponding to the third injection holes 25 is the horizontal direction, and also in that the substitution gas is supplied only to the third gas diffusion space 72 between the first gas diffusion space 23 and the third gas diffusion space 72 because only the material gas is supplied to the first gas diffusion space 23. Accordingly, in the gas shower head 2C, the substitution gas is not discharged from the first injection holes 21 unlike the above-described examples. The other components are the same as those of the gas shower head 2C of the third example.

The opening direction of the third injection holes is not necessarily directed downward. Since, however, the amount of the substitution gas flowing toward the second gas diffusion space 24 and the plasma generation chambers 40 increases, it is preferable that the opening direction of the third injection holes is directed downward as in the third example in order to quickly purge the processing space 10.

In the gas shower head 2C, in step S1 described above, the material gas is discharged from the first injection holes 21, and the plasma-excited reaction gas is discharged from the second injection holes 221. During steps S1, S2, and S4 in which the supply destination changing valve 61 is opened, the substitution gas is discharged from the third injection holes 251 toward the second injection holes 221 via the third gas diffusion space 72. Due to the flow of the substitution gas, the activated reaction gas is prevented from leaking into the processing space 10 and, also, the material gas is prevented from flowing into the plasma generation chambers 40.

In the case of using the gas shower heads 2B and 2C of the third and fourth examples, the substitution gas discharged from the third injection holes 25 and 251 serves as a gas curtain for preventing the reaction gas from leaking from the second gas diffusion space 24 to the processing space 10. Therefore, the flow of the plasma-excited reaction gas into the processing space 10 side may be suppressed by the gas curtain without providing the supply destination changing valve 61, the first evacuation path 62, and the first evacuation mechanism 63.

For example, in the steps of supplying the material gas and the substitution gas to the processing space 10 as in steps S1, S2, and S4 described above, the substitution gas is discharged from the third injection holes 25 and 251, and the inflow of the reaction gas into the processing space 10 is suppressed by the substitution gas. Accordingly, the reaction plasma-excited reaction gas is stored in the flow path extending from the plasma generation chambers 40 to the second gas diffusion space 24. On the other hand, in the step of supplying the reaction gas to the processing space 10 as in step S3 described above, the discharge of the substitution gas from the third injection holes 25 and 251 is stopped. Accordingly, the stored reaction gas is discharged from the second injection holes 22 into the processing space 10.

### Fifth Example of Gas Shower Head

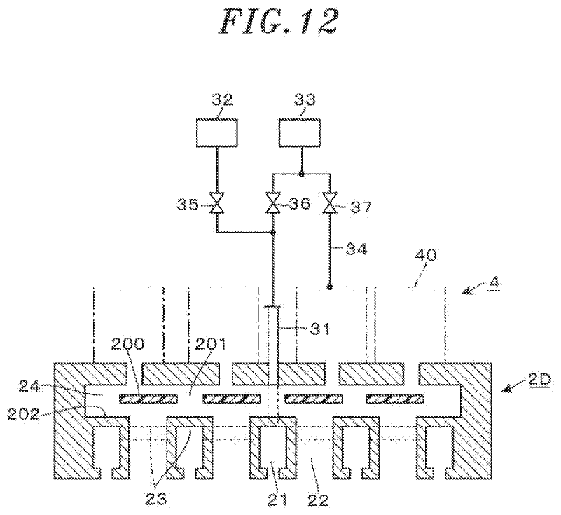

A fifth example of the gas shower head will be described with reference to FIG. 12. A gas shower head 2D of this example is different from the gas shower heads 2 to 2C described above in that the second gas diffusion space 24 is provided with a restricting portion 200.

In the description, the surface defining the lower end of the second gas diffusion space 24 is defined as a bottom surface 202. The restricting portion 200 is separated from the lower end and the upper end of the second gas diffusion space 24, and is formed as a plate-like body, for example, disposed horizontally to face the bottom surface 202. The restricting portion 200 has through-holes 201 formed in a longitudinal direction, more specifically, in the vertical direction, at positions that do not overlap the second injection holes 22 in plan view. Further, the restricting portion 200 in this example is made of a dielectric. In this example, the case where the gas shower head 2 of the first example is provided with the restricting portion 200 is described. The other components are the same as those of the gas shower head 2.

The restricting portion 200 is disposed to overlap the second injection holes 22 when viewed from the processing space 10 side. Due to the presence of the restricting portion 200, a relatively small gap is formed between the bottom surface 202 and the bottom surface of the restricting portion 200, and a narrow flow path is formed. Therefore, when the gas in the processing space 10 flows to the second gas diffusion space 24, the pressure loss is relatively large. Hence, it is possible to more reliably prevent the material gas from flowing from the processing space 10 into the second gas diffusion space 24 and the plasma generation chambers 40 and reacting with the reaction gas.

Due to the restricting portion 200, the radicals in the reaction gas supplied from the plasma generation chambers 40 pass through the flow path that is bent and has a relatively small gap to reach the second injection holes 22, and are supplied to the processing space 10. Therefore, due to the restricting portion 200, the pressure loss of the radicals also increases, and the flow rate of the radicals directed toward the processing space 10 is restricted. By appropriately setting the gap between the restricting portion 200 and the bottom surface 202, the pressure loss of the radicals becomes appropriate, which makes it possible to adjust the flow rate of the radicals and optimize the quality of the film formed on the wafer W.

The restricting portion 200 is made of a dielectric, and thus traps ions contained in the plasma-activated reaction gas. Although the reaction gas contains radicals and ions as described above, the ions are removed by the contact with the dielectric on the surface of the restricting portion 200. Therefore, the amount of ions in the reaction gas can be controlled, and desired quality of the film formed on the wafer W can be obtained. In order to trap the ions, at least the surface of the restricting portion 200 may be made of a dielectric.

In the configuration in which the ions are trapped by the restricting portion 200, the power may or may not be supplied from the second RF power supply 16 to the placing table 12 for bias generation.

### Third Example of Plasma Generation Part

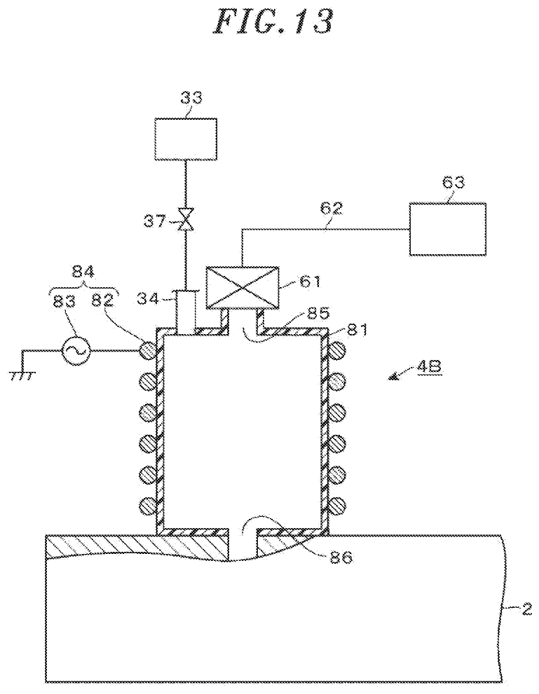

A third example of the plasma generation part will be described with reference to FIG. 13. A plasma generation part 4B of this example uses inductively coupled plasma (ICP). The plasma generation part 4B includes a plasma generation chamber 81 made of a dielectric, for example, and formed in a cylindrical shape with a bottom and a lid, and a coil 82 wound around the plasma generation chamber 81. An RF power is applied from an RF power supply 83 to the coil 82. A plasma generation mechanism 84 includes the coil 82 and the RF power supply 83.

The plasma generation chamber 81 is connected to the reaction gas supply source 33 through the second gas supply line 34, and the reaction gas is supplied into the plasma generation chamber 81 by opening the valve 37. The plasma generation chamber 81 has a first outlet 85 on an upper surface thereof and a second outlet 86 on a bottom surface thereof. The first outlet 85 is connected to the first evacuation mechanism 63 by the first evacuation path 62 having the supply destination changing valve 61, and the second outlet 86 is connected to the second gas diffusion space 24 of the gas shower head 2.

In this example, the reaction gas is supplied into the plasma generation chamber 81, and the supply destination changing valve 61 is opened to evacuate the plasma generation chamber 81 by the first evacuation mechanism 63. In this manner, the reaction gas flows, and the RF power is applied from the RF power supply 83 to the coil 82. Accordingly, high voltage variable magnetic field and high frequency variable magnetic field can be obtained at the same time, so that inductively coupled plasma is generated, and the reaction gas is activated by the plasma. The other components and the film forming method are the same as those of the film forming apparatus 1 of the first embodiment. Also in the case of using the plasma generation part 4B, the same effect as that of the film forming apparatus 1 of the first embodiment can be obtained.

The film forming apparatus 1 of the present disclosure may use, as the plasma generation part, various plasma generation sources having different generation methods. The time required for plasma to ignite or stabilize varies depending on plasma generation methods. However, in the technique of the present disclosure, plasma is always/constantly generated in the plasma generation chamber, and the supply and supply stop of the plasma-activated reaction gas to the processing space can be controlled by opening and closing the supply destination changing valve. Therefore, even if the time required for ignition or stabilization varies depending on types of plasma, the supply time of the plasma-activated reaction gas is not affected, which makes it possible to facilitate the design of the film forming apparatus 1.

Although an example of forming a Ti film using TiCl₄ as the first processing gas (the material gas) and Ar gas as the second processing gas (the reaction gas) has been described above, the combination of the first processing gas and the second processing gas is not limited thereto. For example, another inert gas such as N₂ (nitrogen) gas, or H₂ (hydrogen) gas may be used as the second processing gas (the reaction gas), other than Ar. Further, a gas in which Ar gas is combined with an inert gas or H₂ gas may be used as the second processing gas. Further, the film forming apparatus of the present disclosure may be applied to formation of a TiN film, a W film, a WN film, a TaN film, and a TaCN film in addition to a Ti film. It may be applied to formation of a film other than a metal film. For example, it may be applied to formation of a film containing silicon.

The above-described embodiments may be combined with each other. In the present disclosure, the plasma generation chamber provided with the plasma generation mechanism is not limited to that in the above examples, and plasma may be generated using RF parallel plate type capacitive coupling, a very high frequency (VHF), microwaves, or the like.

The supply destination changing valve 61 is not necessarily provided at the above-described position, and may be provided at any position on the first evacuation path 62. If the supply destination changing valve 61 is too close to the first evacuation mechanism 63 with respect to the plasma generation chambers 40, it may become difficult to quickly switch the evacuation flow direction in the plasma generation chambers 40. Therefore, it is preferable that the supply destination changing valve 61 is appropriately separated from the first evacuation mechanism 63.

In the above-described examples, the first evacuation mechanism 63 and the second evacuation mechanism 66 are provided as the evacuation mechanism for upward evacuation and the evacuation mechanism for downward evacuation, respectively. However, the evacuation mechanisms may be shared. Specifically, the downstream side of the valve 64 of the second evacuation path 65 may be connected to the downstream side of the supply destination changing valve 61 of the first evacuation path 62, and each of the processing space 10 and the plasma generation chamber 40 may be evacuated by the first evacuation mechanism 63.

Further, it is not necessary to supply the plasma-activated reaction gas in the plasma generation chambers 40 to the processing space 10 via the gas shower head 2. For example, a nozzle may be provided at the ceiling plate or the sidewall of the processing vessel 11. In that case, the nozzle and the plasma generation chambers 40 may be connected by pipes, and the activated reaction gas may be discharged from the nozzle. However, in order to form a film on the wafer W while ensuring high uniformity, it is preferable to supply the reaction gas to the wafer W via the gas shower head as described above.

In the above-described examples, the supply of the reaction gas to the plasma generation chambers 40 and the plasma generation are continuously performed during the film formation. However, the supply of the reaction gas to the plasma generation chambers 40 and the plasma generation may be stopped for a part of steps S1, S2, and S4 in which it is unnecessary to supply the reaction gas to the processing space 10, for example. However, the above-described plasma ignition problem can be more reliably solved by continuously performing the supply of the reaction gas to the plasma generation chambers 40 and the plasma generation.

### Other Applications

Further, it should be noted that the embodiments of the present disclosure are illustrative in all respects and are not restrictive. The above-described embodiments may be omitted, replaced, or changed in various forms without departing from the scope of the appended claims and the gist thereof.

### DESCRIPTION OF REFERENCE NUMERALS

W: semiconductor wafer
1: film forming apparatus
10: processing space
11: processing vessel
40: plasma generation chamber
5: plasma generation mechanism
61: supply destination changing valve
63: first evacuation mechanism

1. A film forming apparatus that includes a processing vessel accommodating a substrate and having therein a processing space evacuated to a vacuum atmosphere, and forms a film on a substrate by performing multiple times a cycle of supplying to the processing space a first processing gas, a substitution gas for replacing an atmosphere of the processing space, and a plasma-activated second processing gas, and the substitution gas in that order, the film forming apparatus comprising:
a plasma generation chamber provided with a plasma generation mechanism configured to activate the second processing gas;
an evacuation mechanism configured to evacuate the plasma generation chamber;
a first flow path disposed in the processing vessel to supply the first processing gas to the processing space;
a second flow path that is partitioned from the first flow path such that a downstream end is opened to the processing space and an upstream end is connected to the plasma generation chamber, and is not opened or closed by a valve;
a gas supply mechanism configured to supply the first processing gas, the second processing gas, and the substitution gas to the first flow path, the plasma generation chamber, and a substitution gas flow path configured to supply the substitution gas to the processing space, respectively; and
a supply destination changing valve that is disposed at any position on an evacuation path that connects the plasma generation chamber and the evacuation mechanism, and configured to be opened and closed during repetitive execution of the cycle so that a supply destination of the plasma-excited second processing gas switches between a downstream side of the position on the evacuation path and the processing space.

2. The film forming apparatus of claim 1, further comprising:
a gas shower head forming a ceiling portion of the processing vessel,
the first flow path has a plurality of first injection holes formed in a longitudinal direction to open to the processing space, and a first gas diffusion space formed at an upstream side of the plurality of first injection holes and commonly connected to the plurality of first injection holes,
the second flow path has a plurality of second injection holes formed in the longitudinal direction to open to the processing space, and a second gas diffusion space formed at an upstream side of the plurality of second injection holes and commonly connected to the plurality of second injection holes, and
the plurality of first injection holes, the plurality of second injection holes, the first gas diffusion space, and the said second gas diffusion space are formed in the gas shower head.

3. The film forming apparatus of claim 2, wherein the plasma generation chamber is stacked on the gas shower head.

4. The film forming apparatus of claim 2, wherein a diameter of the plurality of second injection holes increases downward.

5. The film forming apparatus of claim 2, wherein the gas shower head comprises:
a third injection hole that opens in a wall surface forming the plurality of second injection holes and discharges a gas into the plurality of second injection holes; and
a third flow path partitioned from the first flow path and the second flow path on the upstream side of the third injection hole, and
the gas supply mechanism supplies a sealing gas for sealing the plurality of second injection holes to the third flow path during a period in which the first processing gas is supplied to the first flow path.

6. The film forming apparatus of claim 5, wherein the third injection hole opens to discharge the sealing gas toward a position lower than the third injection hole on the wall surface forming the plurality of second injection holes.

7. The film forming apparatus of claim 5, wherein the sealing gas is also used as the substitution gas, and the third flow path is the substation substitution gas flow path.

8. The film forming apparatus of claim 2, wherein the substitution gas flow path serves as the first flow path, and
the first processing gas and the substitution gas are sequentially supplied from the gas supply mechanism to the first flow path during a period in which the supply destination changing valve is opened.

9. The film forming apparatus of claim 2, wherein a restricting portion for preventing a gas from flowing into the second gas diffusion space from the plurality of second injection holes is formed at the second gas diffusion space to be separated from a lower end of the second diffusion space, and the restricting portion has a plurality of through-holes formed in the longitudinal direction at positions that do not overlap the plurality of second injection holes in a plan view.

10. The film forming apparatus of claim 9, wherein a surface of the restricting portion is made of a dielectric in order to suppress supply of ions contained in the plasma-activated second processing gas to the substrate.

11. The film forming apparatus of claim 1, wherein a plurality of the plasma generation chambers are provided,
an evacuation space commonly used for the plurality of plasma generation chambers is provided above the plurality of plasma generation chambers, and
an upstream side of the evacuation path is connected to the evacuation space.

12. The film forming apparatus of claim 1, wherein a plurality of the plasma generation chambers are provided, and
the valve is provided for each of the plurality of plasma generation chambers.

13. The film forming apparatus of claim 1, wherein the plasma generation chamber includes a pipe body forming an annular space,
the plasma generation mechanism includes:
an annular magnetic body surrounding a partial wall of the pipe body;
a radio frequency (RF) power supply; and
a coil to which a power from the RF power supply is supplied and wound around the magnetic body.

14. The film forming apparatus of claim 1, wherein the plasma generation chamber is made of a dielectric, and
the plasma generation mechanism includes:
a radio frequency (RF) power supply; and
a coil to which a power from the RF power supply is supplied and wound around the plasma generation chamber.

15. A film forming method for forming a film on a substrate accommodated in a processing vessel by executing multiple times a cycle of supplying a first processing gas, a substitution gas for replacing an atmosphere in a processing space in the processing vessel, a plasma-activated second processing gas, and the substitution gas to the processing space in that order, the method comprising:
evacuating the processing space to a vacuum atmosphere;
activating the second processing gas in a plasma generation chamber having a plasma generation mechanism;
evacuating the plasma generation chamber using an evacuation mechanism;
supplying the first processing gas from a gas supply mechanism to a first flow path, wherein the first flow path is formed in the processing vessel to supply the first processing gas to the processing space;
supplying the second processing gas from the gas supply mechanism to a second flow path, wherein the second flow path is not opened and closed by a valve and is partitioned from the first flow path such that a downstream end is opened to the processing space and an upstream end is connected to the plasma generation chamber;
supplying the substitution gas from the gas supply mechanism to a substitution gas flow path for supplying the substitution gas to the processing space; and
during repetitive execution of the cycle, opening/closing a supply destination changing valve disposed at any position on an evacuation path that connects the plasma generation chamber and the evacuation mechanism, and switching a supply destination of the plasma-activated second processing gas between a downstream side of the position on the evacuation path and the processing space.
